(19) United States
(12) Patent Application Publication
(10) Pub. No.: US 2026/0216763 A1
(43) Pub. Date: Jul. 30, 2026

(54) WET CLEANING METHOD FOR THE DOOR OF FOUP

(71) Applicant: ASIA NEO TECH INDUSTRIAL CO., LTD., TAOYUAN CITY (TW)

(72) Inventors: PU-CHANG YEH, TAOYUAN CITY (TW); CHAO-MING CHENG, TAOYUAN CITY (TW)

(21) Appl. No.: 19/271,477

(22) Filed: Jul. 16, 2025

(30) Foreign Application Priority Data
Jan. 25, 2025 (TW) 114103682

(51) Int. Cl. B08B 9/08; B08B 9/093; H01L 21/673

(52) U.S. Cl. CPC B08B 9/0821; B08B 9/093; H10P 72/1916; H10P 72/1922

(57) ABSTRACT

A wet cleaning method for the door of FOUP, including placing the door horizontally, such that an inner surface of the door with an annular seal ring is exposed upward, and an outer surface of the door with a plurality of functional slots is exposed downward, and the inner surface of the door and the seal ring are flushed from top to bottom by the cleaning solution. Specifically, the cleaning path of the cleaning solution excludes passing through the outer surface and the functional slot holes, so as to prevent the cleaning solution from flowing into the inner compartment of the door and accumulating therein.

### BACKGROUND OF INVENTION

### 1. Field of the Invention

The present invention relates generally to FOUP cleaning technique, and more particularly to a wet cleaning method for door of FOUP.

### 2. Description of Related Art

In the present invention, a FOUP refers to the commonly seen Front-Opening Unified Pod, which is composed of a hollow shell locked with a door. In semiconductor manufacturing processes, FOUPs are commonly used to house wafers and are filled with specific gases. Subsequently, the FOUPs are transported by Overhead Hoist Transport (OHT) systems to various workstations for semiconductor wafer processing. Furthermore, FOUPs are gradually utilized to house substrates, panels, or other precision components. This enables their transportation via an OHT system to respective processing stations for necessary manufacturing steps.

In the semiconductor manufacturing process for example, the basic structure and specifications of FOUPs have been standardized and restricted. Please refer to FIG. 1a to FIG. 1c. As shown, the structure of the FOUP 10 comprises a shell 11 and a door 12. Specifically, FIG. 1a shows the perspective view of the shell 11 and the door 12 locked together as a whole. FIG. 1b shows the perspective view of the door 12 unlocked and separated from the shell 11. As shown, the shell 11 is roughly a hollow quadrilateral body and has a housing compartment 16 enclosed by the shell body and an opening 13 communicating with the housing compartment 16 and open to the outside. The housing compartment 16 is enclosed by an inner wall 110. The inner wall 110 has layered slots 111 for positioning chips. A flange 15 (commonly referred to as a “mushroom head”) is formed on one side wall of the shell 11, specifically designed for an OHT to clamp the FOUP. In addition, the door 12 is roughly a quadrilateral body and can cover the opening 13 of the shell 11 by means of locking. As shown in FIG. 1b and FIG. 1c, the door 12 has an outer surface 121 exposing outside the shell 11, an inner surface 122 located on the opposite side of the outer surface 121 and hidden inside the shell, and an end wall 123 formed by extending the periphery of the inner surface 122. The end wall 123 encloses the outer surface 121.

Further, FIG. 1b discloses that the end wall 123 is provided with a plurality of clamping ears 17 configured in an externally protruding manner, which are used to engage with the door 12 on the shell 11. The clamping ears 17 are respectively fitted inside an ear hole 171 to allow extension and retraction relative to the end wall 123. Moreover, between the outer surface 121 and the inner surface 122, there is an inner compartment 125 for accommodating an unlocking mechanism (not shown in the figure). The locking mechanism is in an interconnected relationship with said clamping ears 17 to control the clamping ears 17 to extend out of or retract into the end wall 123. Additionally, FIG. 1b shows that the outer surface 121 comprises a plurality of functional slot holes A communicating with the inner compartment 125. The plurality of functional slot holes A include paired key holes A1, paired positioning holes A2, and a plurality of drain holes A3. Specifically, the end wall comprises a plurality of ear holes communicating with the inner compartment. Each ear hole extends outward to form a clamping ear for locking the shell.

The paired keyholes A1 are designed for insertion of external keys to actuate the unlocking mechanism, which enables the clamping ear 17 on the ear hole 171 to retract into the end wall 123, thereby opening the door 12 on the shell 11. Conversely, the door 12 can be securely latched and locked onto the opening 13 of the shell 11 through the extension of the clamping ear 17. Specifically, the ear hole 171 is connected to the inner compartment 125, such that the clamping ear 17 can be driven by the unlocking mechanism.

Additionally, the pair of positioning holes A2 are used to position the door 12 on the workbench surface during the manufacturing process, or to position the FOUP 10 with the shell 11 and the door 12 locked together. Furthermore, the plurality of drain holes A3 is also connected to the inner compartment 125. Thus, these drain holes A3 are used to drain accumulated water within the inner compartment 125 (as will be detailed later). Moreover, it is to be noted that some conventional doors 12 may incorporate additional slot holes (not shown in the figure) on the end wall 123 that communicate with the inner compartment 125.

Furthermore, FIG. 1c reveals that the inner surface 122 has a ring-shaped airtight seal ring 14 for maintaining the airtight effect when the door 12 and the shell 11 are locked and combined. In addition, the inner surface 122 of the door 12 also has a plurality of slots 124 that can correspond to the slots 111 in the housing compartment 16 layer by layer to hold chips.

Said FOUP 10 requires cleaning after being used for a certain period to remove harmful substances accumulated or remaining on the shell 11 and the door 12. These harmful substances include dust particles, volatile organic compounds (VOC), sulfur dioxide (SO2), Amines, Acids, Ammonia (NH3) etc. The above cleaning procedure removes the harmful substances from the FOUPs and ensures good quality of the process components (such as wafers) during manufacturing. Therefore, in processing area stations where FOUPs 10 are used to transport process components for production, often a special cleaning area station designed for FOUP cleaning is provided to execute the FOUP cleaning procedure.

In the cleaning area station, at least one cleaning machine is generally provided for the washing step only in the cleaning procedure. Alternatively, the same cleaning machine may even execute wet cleaning, water removal, and drying steps. Each cleaning machine has a cleaning chamber for placement of the FOUP 10 to be cleaned. The cleaning machine is also configured with fluid pipelines to supply cleaning solution and blowing air, as well as heating elements that supply thermal energy for drying.

Before cleaning, the door 12 and the shell 11 of the FOUP 10 must firstly be unlocked and separated before they are transported by an automatic machine such as a robotic arm to the cleaning machine to receive cleaning through cleaning solution, gas, and heating elements.

In the present invention, the focus is on exploring the wet cleaning of the door 12 and shell 11 using a cleaning solution in the cleaning machine in the prior art. In other words, according to the prior art, the door 12 and shell 11 can be placed in the cleaning chamber of the same cleaning machine to be simultaneously rinsed by the fluid, or the door 12 and shell 11 can be classified, and the cleaning chambers of multiple cleaning machines can be used to clean the door 12 and the shell 11 respectively.

Furthermore, manufacturers in the industry maintain stringent cleanliness requirements for the surrounding walls and surfaces of the housing compartment 16 to ensure process quality for workpieces (e.g., wafers). In other words, the cleanliness standards for the inner surface 122 of the door 12 (including slots 124) and its airtight seal ring 14, as well as the inner wall 110 of shell 11 (including slot 111), are significantly higher than those for the outer surface 122 of the door 12 and the outer walls 112 of the shell 11. This prevents harmful substances from contaminating workpieces held inside the housing compartment 16.

Please refer to FIG. 2a, which discloses the existing first type of FOUP cleaning machine 21 that can place said shell 11 with its opening 13 facing downward inside its cleaning chamber 210, and position said door 12 vertically on one side of the shell 11 in a spaced manner, such that the inner surface 122 of the door 12 faces towards the shell 11 while the outer surface 121 faces away from the shell 11. In addition, multiple nozzles 211, 212, and 213 are arranged between the inner surface 122 and the outer wall 112 of the shell 11, around the outer wall 11 of the shell 11, and within the housing compartment 16 respectively, to synchronously supply cleaning solution for cleaning the door 12 and the shell 11.

However, although some of the multiple nozzles 211 are arranged between the inner surface 122 and the shell 11 to simultaneously flush the inner surface 122 with high cleanliness requirements, the airtight seal ring 14 on it, and the outer wall 112 of the shell 11 in the lateral direction, during the wet cleaning process, the cleaning solution will splash everywhere in the cleaning chamber 210, and the inner surface 122 and the airtight seal ring 14 with high cleanliness requirements on the door 12 are adjacent to the outer wall 112 of the shell 11, resulting in the inner surface 122 and the airtight seal ring 14 being easily contaminated by the cleaning solution splashing from the outer wall 112 of the shell 11 during the cleaning process. In addition, although the outer surface 121 with multiple functional slot holes A (as shown in FIG. 1b) faces outward and is not directly exposed to the cleaning solution, the cleaning solution splashing everywhere in the cleaning chamber 210 can still flow into the inner compartment 125 through the key holes A1, the drain holes A3, and the ear holes 171 on the outer surface 121 shown in FIG. 1b, or other through-holes and accumulate there. Moreover, since the door 12 is flushed in a vertical position, it is not conducive to the full discharge of the cleaning solution accumulated in the inner compartment 125 from the ear holes 171. Also, it is known that the more cleaning solution accumulates in the inner compartment 125, the longer the cleaning time required for air blow water removal and drying by the heating element after cleaning, resulting in lowered cleaning efficiency of the door 12 or too much man-hour for cleaning the door 12. Therefore, improvement is urgently needed.

Please refer to FIG. 2b, which discloses the existing second-type FOUP cleaning machine 22. Its difference from the cleaning machine shown in FIG. 2a lies in that, within the cleaning chamber 220, said door 12 is horizontally placed above the shell 11, with the inner surface 122 of the door 12 facing downward and the outer surface 121 facing upward. Some of the multiple nozzles 221 and 222, namely the nozzles 221, spray the cleaning solution from bottom to top to rinse the inner surface 122 with a higher cleanliness requirement and the airtight seal ring 14 on it.

However, since the inner surface 122 with a higher cleanliness requirement and the airtight seal ring 14 on the door 12 face downward and are adjacent to the outer wall 112 of the shell 11 for flushing, the inner surface 122 and the airtight seal ring 14 are still prone to cross-contamination by the cleaning solution splashing from the outer wall 112 of the shell 11 during the cleaning process. In addition, although the outer surface 121 with multiple functional slot holes A (as shown in FIG. 1b) is exposed upward and does not directly face the cleaning solution, the cleaning solution splashing everywhere in the cleaning chamber 210 will still flow into the inner compartment 125 through the key hole A1 and the drain holes A3 on the outer surface 121, and the ear hole A4 on the end wall 123, or other through-holes, and accumulate there. Moreover, since both the drain holes A3 and the key hole A1 face upward, it is even more unfavorable for draining the cleaning solution accumulated in the inner compartment 125. Furthermore, the more cleaning solution accumulates in the inner compartment 125, the longer the cleaning time required for air blow water removal and drying with heating elements after cleaning. Therefore, it also causes the problem of lowered cleaning efficiency of the door 12, or too much man-hour for cleaning the door 12. So, improvements are still needed.

### SUMMARY OF THE INVENTION

The technical problem to be addressed by the present invention is: minimizing the accumulation of cleaning solution within the inner compartment of the door shown in FIG. 1a to FIG. 1c during the rinsing process, or ensuring smooth drainage of accumulated cleaning solution through the drain holes even if such accumulation occurs.

The present invention provides a wet cleaning method for the door of the FOUP shown in FIG. 1a to FIG. 1c, which includes horizontally placing the door such that the inner surface with the annular airtight seal ring is exposed upward and the outer surface with the functional slot holes is exposed downward, defining a downward-directed door cleaning path, and supplying the cleaning solution to flush the inner surface and the airtight seal ring of the door along this path. Specifically, the door cleaning path avoids passing through the outer surface and the functional slot holes. The door is placed on a pair of clamps to be rinsed by the cleaning solution, and the clamps shield the clamping ears and ear holes from contact with the cleaning solution.

In a further implementation, the defined direction of the door cleaning path from top to bottom includes vertical, diagonal, or a combination thereof.

In a further implementation, the wet cleaning method is implemented in a cleaning chamber, where the cleaning solution supplied by the door cleaning path is provided by a plurality of door nozzles configured inside the cleaning chamber. Specifically, the cleaning chamber provides a support frame for placing the door, and the clamps are configured around a horizontal surface area of the support frame.

In a further implementation, when the door is placed, the clamp swings under the gravity of the door to clamp the door. When the gravity of the door is removed, the clamp releases the door in an automatically swinging and resetting manner by virtue of the moment generated by its own gravity.

In addition, in another implementation, the clamp can be replaced by a bearing seat that generally does not cover the clamping ear and the ear hole, and only provides a clamping effect when the door is placed.

A further implementation also includes: horizontally placing the shell such that the opening of the shell used for securing the door is exposed downward and the shell is positioned below the door, and defining a shell inner wall cleaning path from inside to outside and a shell outer wall cleaning path from outside to inside; supplying cleaning solution to flush the inner wall of the shell along the shell inner wall cleaning path, and supplying cleaning solution to flush the outer wall of the shell along the shell outer wall cleaning path. Specifically, the outer wall of the shell is relatively adjacent to the outer surface of the door and relatively distant from the inner surface of the door. In a further implementation, the cleaning solution supplied through the door cleaning path, the shell inner wall cleaning path, and the shell outer wall cleaning path is provided by multiple nozzles arranged around the cleaning chamber. In another further implementation, the cleaning chamber provides a support frame to stack the door and the shell in layers, and the clamps are positioned around a horizontal surface area of the support frame.

The efficacy to be realized by the present invention includes:
1. Orienting the door's inner surface with higher cleanliness requirements and the airtight seal ring upward to directly receive downward-flowing cleaning solution while positioning them away from the shell's outer wall that may easily cause splashing of the cleaning solution, thereby protecting the inner surface and airtight seal ring of the door from contamination by the cleaning solution.
2. Orienting the outer surface of the door with functional slot holes downward to facilitate drainage of inadvertently infiltrated cleaning solution into the inner compartment of the door. This can improve the situation of prolonged air-blow water removal and heating and drying after wet cleaning.
3. Designing the clamp to enable swinging under its self-weight for opening/closing the placement opening, thus simplifying its structure to become more suitable in a wet cleaning environment.
4. Integrating liquid-shielding functionality into the clamp to prevent the cleaning solution from flowing into the inner compartment through the ear holes on the end wall of the door or other through-holes after placement of the door.

Further benefits and advantages of the present invention will become apparent after a careful reading of the detailed description with appropriate reference to the accompanying drawings.

### BRIEF DESCRIPTION OF THE DRAWINGS

FIG. 1a is a perspective view of a prior-art FOUP.

FIG. 1b is an exploded perspective view of the FOUP depicted in FIG. 1.

FIG. 1c is a perspective view of the FOUP in FIG. 1b when the door is flipped.

FIG. 2a is a sectional view of the shell and the door when the first-type prior-art cleaning machine is used to clean the FOUP.

FIG. 2b is a sectional view of the shell and the door when the second-type prior-art cleaning machine is used to clean the FOUP.

FIG. 3 is a flow chart of the execution of the method of the present invention.

FIG. 4a to FIG. 4c are sequential operational views of the cleaning machine used in FIG. 3

FIG. 5a is a perspective view of a preferred embodiment of the bearing seat (clamp) depicted in FIG. 4a.

FIG. 5b to FIG. 5d are sequential operational views of the bearing seat (clamp) depicted in FIG. 5a.

FIG. 6 is a flow chart of the execution of another preferred embodiment of the method of the present invention.

FIG. 7a and FIG. 7b are respectively perspective view and sectional view of the cleaning machine used in FIG. 6.

### DETAILED DESCRIPTION OF THE INVENTION

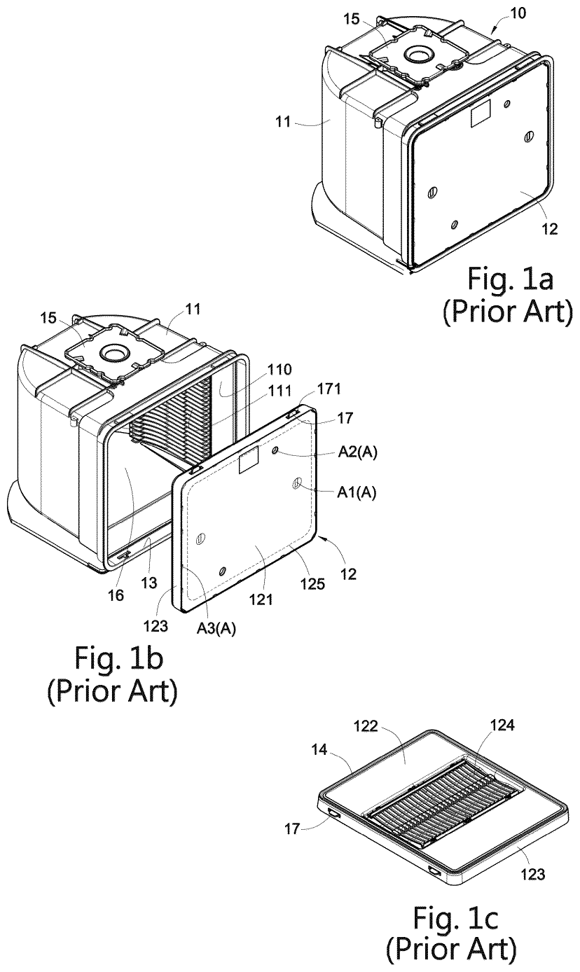

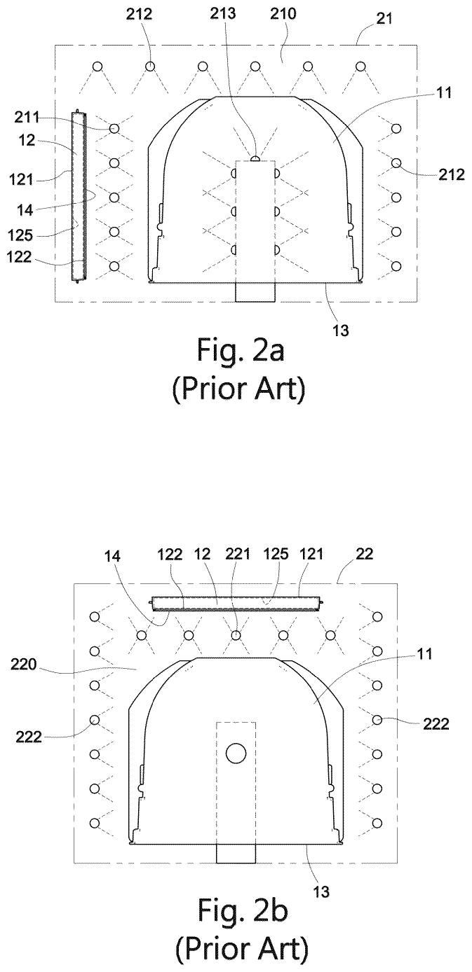

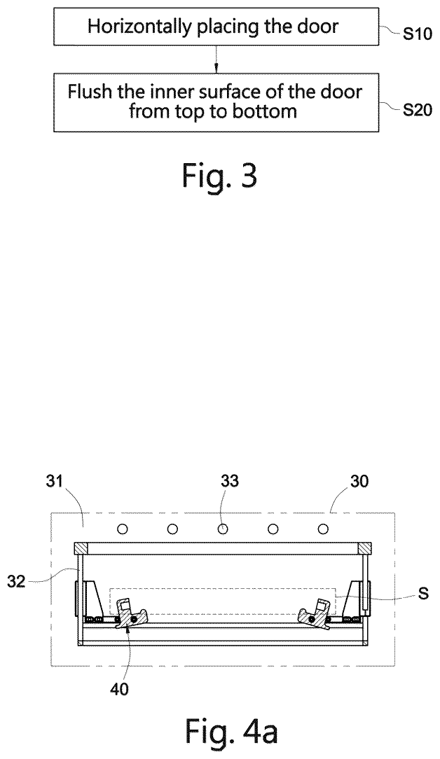

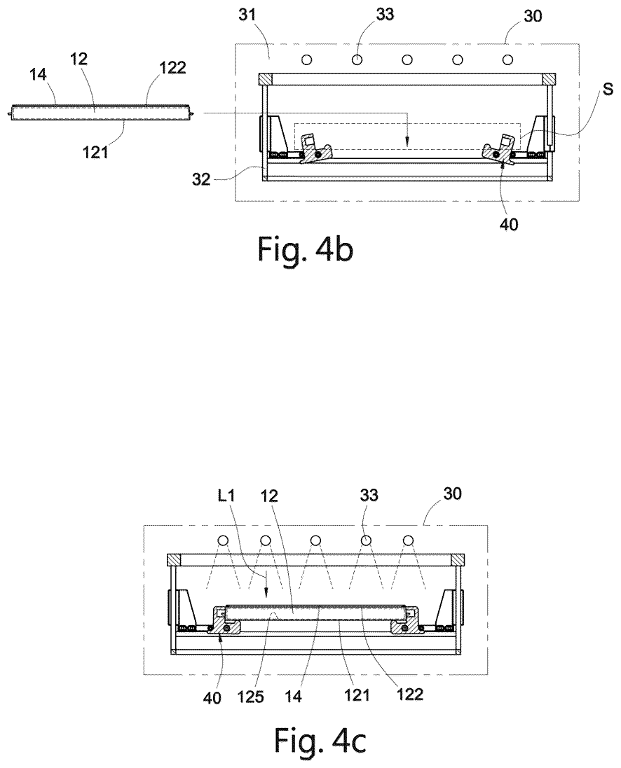

First, please refer to FIG. 3, which illustrates a preferred execution procedure of the wet cleaning method for the door 12 of the FOUP 10 shown in FIGS. 1a to 1c according to the present invention. Also, please refer to FIGS. 4a to 4c collectively, which provide supplementary explanation of the implementation details of the wet cleaning procedure shown in FIG. 3.

In particular, FIG. 4a discloses a cleaning machine 30 according to the present invention, specifically designed for cleaning said FOUP. The cleaning procedure may include wet cleaning, dehydration, and drying steps. In the present invention, the focus is on describing the wet cleaning step performed by the cleaning machine 30 on the FOUP 10 shown in FIG. 1b. Since the FOUP 10 has been unlocked and separated into the door 12 and the shell 11 prior to wet cleaning, the cleaning machine 30 shown in FIG. 4a is primarily applied for wet cleaning of the door 12 only.

Further, the cleaning machine 30 disclosed in FIG. 4a may be formed by an enclosure having a cleaning chamber 31. The cleaning chamber 31 is connected to the atmosphere and accommodates a hollow support frame 32 for carrying the door 12. The support frame 32 can provide a horizontal surface area S to hold the door 12. In applicable implementations, the cleaning machine 30 may include a hatch capable of opening and closing the cleaning chamber 31. The support frame 32 can be moved into and out of the hatch and the cleaning chamber 31 via a lifting mechanism. The support frame 32 may also be equipped with a chamber door to seal the hatch when entering the cleaning chamber 31. Additionally, a plurality of door nozzles 33 for supplying cleaning solution are fixedly installed at intervals in the upper layer of the cleaning chamber 31, and the support frame 32 can be driven by a driver to rotate within the cleaning chamber 31, thereby rotating the door 12 inside the support frame 32 to fully receive rinsing from the cleaning solution sprayed by the door nozzles 33. Moreover, the door nozzles 33 may also be mounted on the support frame 32 to rotate along with the support frame 32 within the cleaning chamber 31 while spraying cleaning solution to rinse the door 12.

FIG. 4b to FIG. 4c sequentially illustrate the implementation details of executing Step S10 to Step S20 shown in FIG. 3, including:
Step S10: Horizontally placing the door.

As shown in FIG. 4b to FIG. 4c, this step can utilize automated machinery such as a robotic arm to move the door 12, positioning it with the inner surface 122 of the door 12 (which has said airtight seal ring 14) facing upward, and placing the door 12 horizontally on the horizontal surface area S of the support frame 32. Specifically, the door 12 can be placed onto the horizontal surface area S either when the support frame 32 extends outward from the hatch of the cleaning machine 30, or when the hatch is opened to expose the horizontal surface area S of the support frame 32, thus be placed on the support frame 32 horizontally.

Further, the horizontal surface area S can be constructed by arranging multiple pairs of bearing seats 40 around the support frame 32 at intervals. In other words, the multiple pairs of bearing seats 40 are positioned on the support frame 32 according to the relative positions of the clamping ears 17 and their ear holes 171 on the end wall 123 of the door 12, or the relative positions of other through-holes on the end wall 123 that connect to the inner compartment 125, and are deployed on the support frame 32 at intervals to form the horizontal surface area S. In this way, the door 12 can be stably placed on the bearing seats 40 while maintaining horizontal stability and immobilization. Herein, the term “horizontal” refers to the general range of the horizontal plane on the ground surface.

The bearing seat 40 can be implemented to have a calibrated horizontal base surface. In addition to providing placement for the door 12, it can also be implemented in the form of a slot seat that holds the corresponding positions of the end wall 123 and/or the outer surface 121 of the door 12 to achieve the effect of horizontal placement. Moreover, in another preferred implementation, the bearing seat 40 can also be implemented in the form of a clamp with a water-blocking function.

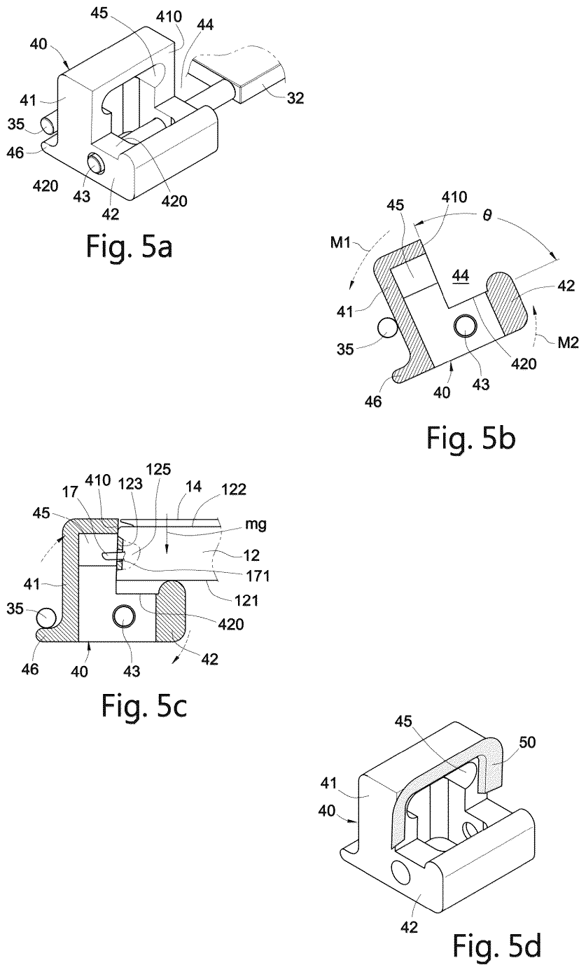

Please refer to FIG. 5a to FIG. 5c together, which disclose a preferred implementation of the bearing seat 40 with a water-blocking function, that is, using a swing clamp as the bearing seat 40. Among them, FIG. 5a and FIG. 5b jointly disclose that the clamp (i.e., the bearing seat 40) is integrally formed by a clamp arm 41 and a seat arm 42 at an included angle θ close to or equal to 90 degrees, making the clamp 40 present an L-shaped slot block. One side of the clamp arm 41 forms a blocking surface 410, one side of the seat arm 42 forms a supporting surface 420, and the included angle θ is formed between the blocking surface 410 and the supporting surface 420, so that an L-shaped placement opening 44 is formed between the blocking surface 410 and the supporting surface 420. Furthermore, a housing space 45 can be formed on the blocking surface 410 of the clamp arm 41 to accommodate the clamping ear 17 protruding from the end wall 123 of the door 12. The enclosed area of the blocking surface 410 is larger than the ear hole 171 or other through-holes to be covered. In a variable implementation, the blocking surface 410 can be formed into one of a gate-shaped body, a Π-shaped body, an inverted U-shaped body, or a straight-shaped body, so that the housing space 45 is enclosed inside or at the bottom edge of the blocking surface 410.

Further, the clamp 40 can also form a pivoting portion 43 and a stopping portion 46. The pivoting portion 43 can be in the form of a pivot hole or a pivot shaft, so that the clamp 40 can be pivotally mounted on the support frame 32 via the pivoting portion 43. Further, the pivoting portion 43 can be provided at the junction of the clamp arm 41 and the seat arm 42, or relatively close to the seat arm 42, so that moment arms are respectively formed between the centers of mass of the clamp arm 41 and the seat arm 42 and the pivoting portion 43. Furthermore, under the action of atmospheric pressure, the clamp arm 41 and the seat arm 42 can each generate a moment with the pivoting portion 43 as the pivot. In the present invention, it is deliberately planned that the moment M1 generated by the clamp arm 41 must be greater than the moment M2 generated by the seat arm 42, so that the clamp 40 can automatically swing upward to open the placement opening 44 under the action of atmospheric pressure without other external forces (as shown in FIG. 5b). Specifically, by planning the volume and weight of the clamp arm 41 and the seat arm 42 and the lengths of the moment arms between their respective centers of mass and the pivoting portion 43, the effect that the moment M1 of the clamp arm 41 is greater than the moment M2 of the seat arm 42 can be achieved.

Further, the stopping portion 46 protrudes from one side of the clamp 40. The support frame 32 is provided with a stopper post 35 extending to the side of the clamp 40. The stopper post 35 can limit the swing angle of the clamp 40 when the clamp 40 swings back and forth.

Specifically, once the moment M1 generated by the self-weight of the clamp arm 41 of the clamp 40 is greater than the moment M2 generated by the self-weight of the seat arm 42, and the clamp 40 swings by its own weight to a state where the placement opening 44 is exposed upward (as shown in FIG. 5b), the stopper post 35 contacts the outer wall on one side of the clamp arm 41 to limit the swing angle of the clamp 40. Here, the placement opening 44 facing upward is used to provide placement for the door 12. Under the self-weight (mg) of the door 12 pressing against the supporting surface 420 of the seat arm 42, the clamp 40 is forced to swing. The stopping portion 46 can be stopped by the stopper post 35 to limit the swing angle of the clamp 40, so as to maintain the placed door 12 in a horizontal position (as shown in FIG. 5c). When the door 12 is taken out from the cleaning chamber 31 by the automatic machinery after cleaning, the clamp 40 is relieved of the gravity of the door 12, and will automatically swing back to release the door 12. As the moment M1 generated by the self-weight of the clamp arm 41 of the clamp 40 is greater than the moment M2 generated by the self-weight of the seat arm 42, the clamp 40 will automatically swing back to the original position shown in FIG. 5b.

In the state shown in FIG. 5c when the door 12 is placed on the clamp 40, the clamp 40 can lean against the end wall 123 of the door 12 through the blocking surface 410 and embed the outer surface 121 of the door 12 through the supporting surface 420. The blocking surface 410 can completely cover the ear hole 171 on the end wall 123 of the door 12, or other through-holes on the end wall 123 that communicate with the inner compartment 125, and the housing space 45 can accommodate the clamping ear 17. Therefore, once the door 12 is placed horizontally (as shown in FIG. 4b) in the placement opening 44 of the clamp 40 around the horizontal surface area S of the support frame 32 (as shown in FIG. 4c and FIG. 5c), in addition to providing horizontal placement for the door 12, the clamp 40 also has the function of preventing the cleaning solution from flowing into the inner compartment 125 through the ear hole 171 on the end wall 123 of the door 12 and accumulating therein. That is to say, the clamp 40 has the additional function of shielding the clamping ear 171 and its ear hole 171 from contacting the cleaning solution. In addition, referring to FIG. 5d, another embodiment of the clamp 40 is disclosed, which includes arranging a soft pad 50 on the blocking surface 410 adjacent to the placement opening 44. The soft pad 50 can be fixed by means of adhesion or snap-fitting. When the end wall 123 of the door 12 leans against the soft pad 50, it can provide good anti-slip and water-shielding functions.

Step S20: Flush the inner surface of the door from top to bottom.

As can be seen from FIG. 4c, a plurality of the door nozzles 33 arranged on the upper layer of the cleaning chamber 31 can spray the cleaning solution from top to bottom following the direction of the gravitational force. Accordingly, a door cleaning path L1 is defined, which is the path for a plurality of the door nozzles 33 to spray the cleaning solution from top to bottom, and the direction of the door cleaning path L1 may include vertical, diagonal, or a combination thereof. Since the inner surface 122 with higher cleanliness requirements and the airtight seal ring 14 of the placed door 12 face upward, they are relatively far away from the outer wall 112 of the shell 11 that may easily cause splashing of the cleaning solution. Therefore, the cross-contamination of the inner surface 122 and the airtight seal ring 14 by the cleaning solution can be reduced. Moreover, the inner surface 122, or even the inner surface 122 and the end wall 123, can be fully rinsed directly by the cleaning solution sprayed along the door cleaning path L1 to remove harmful substances attached to the inner surface 122 and its airtight seal ring 14.

Further, since the outer surface 121 of the placed door 12 is exposed downward, a plurality of the functional slot holes A exposed on the outer surface 121 (as shown in FIG. 1b) also open downward, and thus will not be rinsed by the cleaning solution sprayed along the door cleaning path L1. Accordingly, the door cleaning path L1 is defined to exclude passing through the outer surface 121 and the functional slot holes A. It is also known that the inner compartment 125 of the door 12 can also open downward through a plurality of partial functional slot holes A. Therefore, even if some cleaning solution sprayed or splashed in other directions in the cleaning chamber 31 accidentally flows into the inner compartment 125 through the functional slot holes A and the ear holes 171, the inner compartment 125 can smoothly drain the cleaning solution due to its downward-opening feature. In addition, the clamp 40 has the additional function of shielding the clamping ear 17 and its ear hole 171 from contact with the cleaning solution. Therefore, the present invention can fully prevent the cleaning solution from accumulating in the inner compartment 125 of the door 12, which may cause problems such as time-consuming air blow water removal and heat drying in the subsequent process.

In the above content, the clamp 40 is an optional additional implementation part. In other words, all applications that do not use the clamp 40 and still use the original bearing seat that does not have the functions of self-weight swinging and shielding the clamping ear 17 and the ear hole 171 fall within the application scope contemplated by the present invention.

Further, the clamp 40 is not exclusively used to cover the clamping ear 17 and its ear hole 171 on the end wall 123 of the door 12. More specifically, any other decorative or functional through-holes on the end wall 123 of the door 12 that require water-shielding can also be simultaneously covered by the clamp 40 while providing placement for the door 12. It should be noted that the clamp 40 may also be positioned at locations on the end wall 123 without the need to cover such decorative or functional through-holes, and only provide placement for the door 12. Such a configuration also falls within the application scope contemplated by the present invention.

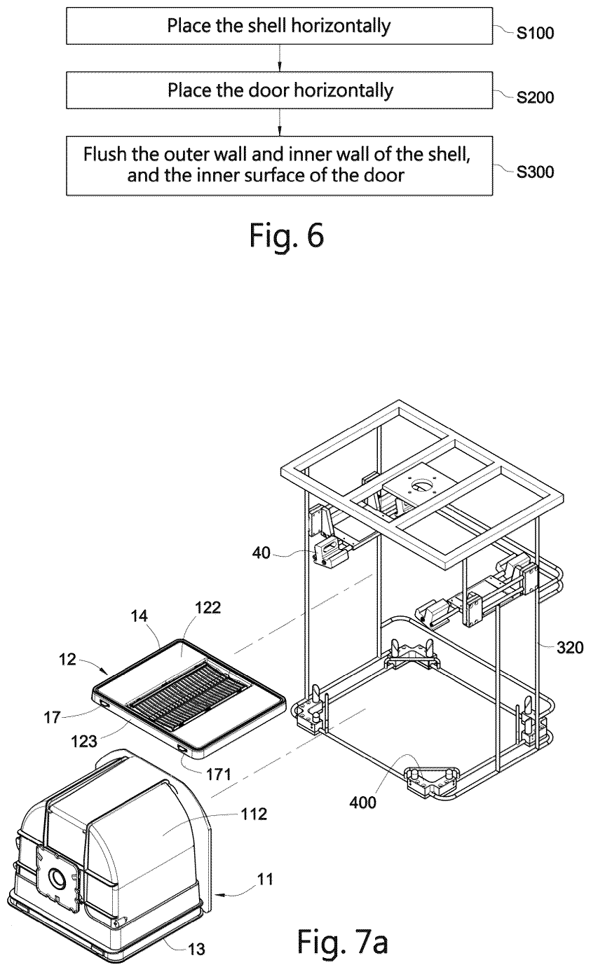

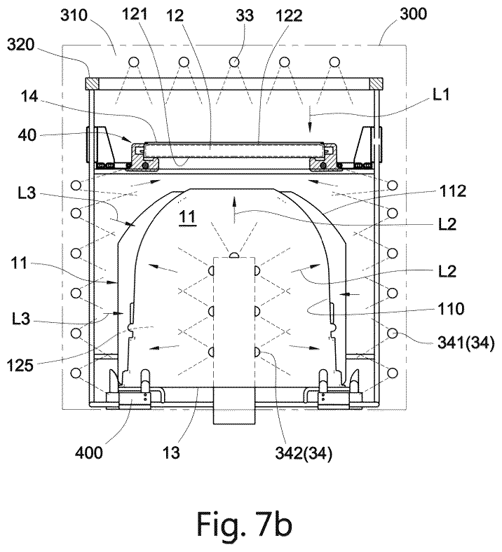

Referring to FIG. 6, another preferred implementation procedure of the wet cleaning method of the present invention for the door of the FOUP is disclosed. Please also refer to FIGS. 7a and 7b for detailed implementation of the wet cleaning process shown in FIG. 6. FIG. 7a and FIG. 7b collectively disclose another type of cleaning machine 300 designed for simultaneous wet cleaning of both the door 12 and shell 11 of the FOUP 10.

The cleaning machine 300 shown in FIG. 7a differs from the cleaning machine 30 shown in FIG. 4a to FIG. 4c in that the hollow support frame 320 accommodated within the cleaning chamber 310 can simultaneously support both the door 12 and the shell 11. Specifically, in a preferred embodiment, the upper space of the support frame 320 is used to hold the door 12 while the lower space holds the shell 11. Consequently, the horizontal surface area S and the bearing seats 40 (or clamps) shown in FIG. 4a are configured in the upper space of the support frame 320, while the lower space contains a plurality of paired bearing seats 400 (or clamps) suitable for placement of the shell 11 (as shown in FIG. 7a).

As illustrated in FIG. 7b, while the upper space of the cleaning chamber 310 is equipped with a plurality of door nozzles 33 supplying cleaning solution, the lower space of the cleaning chamber 310 contains a plurality of shell nozzles 34 to supply cleaning solution. These shell nozzles 34 include a plurality of shell outer wall nozzles 341 distributed around the periphery of the lower space, and a plurality of shell inner wall nozzles 342 positioned at the center of the lower space. Except for these differences, the implementation of the cleaning machine 300 shown in FIGS. 7a and 7b is substantially identical to that of the cleaning machine 30 shown in FIG. 4a to FIG. 4c.

With the cleaning machine shown in FIG. 7a and FIG. 7b, the present invention can sequentially execute the implementation contents from Step S100 to Step S300 as shown in FIG. 6, including:
Step S100: Place the shell horizontally.

This step can use an automatic machine such as a robotic arm to move the shell 11 so that the shell 11 can be placed on the paired bearing seats 400 in the lower-level space of the support frame 320 with the opening 13 facing downward. The bearing seats 400 provide the function of stably maintaining the horizontal position and immobility of the bottom edge of the shell 11. For the rest of the content, please refer to the description of the above-mentioned embodiment shown in FIG. 4a.

Once the shell 11 is placed, the shell nozzles 34 can be located on the inner and outer peripheries of the shell 11. The shell outer wall nozzles 341 are located adjacent to the periphery of an outer wall 112 of the shell 11, and the shell inner wall nozzles 342 can be inserted into the housing compartment 16 of the shell 11 and correspond to an inner wall 110 of the shell 11.

Step S200: Place the door horizontally.

This step is roughly the same as Step 10 of the above-mentioned embodiment. The slight difference is that after the automatic machine such as a robotic arm moves the shell 11 to the bearing seats 400 in the lower-level space of the support frame 320 (that is, after completing Step S100), it then moves the door 12 to the clamp 40 in the upper-level space of the support frame 320 for placement. The implementation content of placing the door 12 is the same as Step S10 of said embodiment.

It must be noted that the implementation order of Step S100 and Step S200 can be reversed or carried out simultaneously. Specifically, the technical focus of the present invention is not on the structural functions of common automatic machines such as robotic arms, but it can use the clamping and carrying functions of automatic machines such as robotic arms to move the shell 11 and the door 12 simultaneously or separately, as well as place the shell 11 and the door 12 simultaneously or separately. All of these belong to the variable application scope of the present invention.

Once the door 12 and the shell 11 are placed as described above, the shell 11 can be located below the door 12, so that the outer wall 112 of the shell 11 is relatively close to the outer surface 121 of the door 12 and relatively far from the inner surface 122 of the door 12 (as shown in FIG. 7b).

Step S300: Flush the outer wall and inner wall of the shell, and the inner surface of the door.

As shown in FIG. 7b, a shell inner wall cleaning path L2 from the inside out is defined for the shell inner wall nozzle 342, and a shell outer wall cleaning path L3 from the outside in define for the shell outer wall nozzle 341. Thus, the shell inner wall nozzle 342 can supply cleaning solution along the shell inner wall cleaning path L2 to flush the inner wall 110 of the shell 11, while the shell outer wall nozzle 341 can supply cleaning solution along the shell outer wall cleaning path L3 to flush the outer wall 112 of the shell 11.

Further, the inner surface 121 of the door 12 is rinsed by the cleaning solution sprayed downward along the door cleaning path L1 via a plurality of the door nozzles 33. Its implementation details are identical to those of said Step 20.

Said door nozzles 33 and shell nozzles 34 can be connected to a cleaning solution supply pipeline to synchronously or sequentially supply the cleaning solution for rinsing the designated portions of the shell 11 and door 12.

Based on the configuration of the embodiment shown in FIG. 7a to FIG. 7b, although the cleaning solution sprayed by the shell outer wall nozzles 34 around the cleaning chamber 310 may still reach the outer surface 121 of the door 12 facing downward and a plurality of functional slot holes A (as shown in FIG. 1b), because the functional slot holesA of the inner compartment 125 are open downward, the cleaning solution can be smoothly drained, thereby avoiding accumulation within the inner compartment 125 of the door 12.

In summary, compared to the prior art, the present invention offers advantages in reducing the time required for subsequent air-blow water removal and thermal drying. In the above descriptions, the terms regarding upper, lower, inner, and outer are defined based on the normal orientation of the objects shown in each diagram.

Although the invention has been explained in relation to its preferred embodiment, it is to be understood that many other possible modifications and variations can be made without departing from the spirit and scope of the invention as hereinafter claimed.

1. A wet cleaning method for the door of a FOUP, wherein the FOUP comprises the door and a shell to be locked by the door, the door has an inner compartment, an outer surface exposed outside the shell, an inner surface located at the opposite side of the outer surface to be hidden inside the shell, and an end wall surrounding the outer surface and inner surface, the outer surface is formed with a plurality of functional slot holes communicating with the inner compartment, the inner surface is provided with an annular airtight seal ring for airtight connection with the shell, the end wall is provided with a plurality of ear holes communicating with the inner compartment, each of the ear holes is provided with a clamping ear protruding in and out for locking the shell, and the door is unlocked and separated from the shell before execution of the wet cleaning method, which includes:
horizontally placing the door so that the inner surface with the annular airtight seal ring is exposed upward and the outer surface with the functional slot holes is exposed downward; and
defining a door cleaning path from top to bottom and supplying cleaning solution to flush the inner surface and the airtight seal ring of the door along the door cleaning path.
Specifically, the door cleaning path excludes passing through the outer surface and the functional slot holes, the door is placed on a pair of clamps to receive the flushing of the cleaning solution, and the clamps cover the clamping ears and the ear holes to prevent them from contacting the cleaning solution.

2. The wet cleaning method for the door of FOUP defined in claim 1, wherein the defined direction of the door cleaning path from top to bottom includes vertical, diagonal, or a combination thereof.

3. The wet cleaning method for the door of FOUP defined in claim 1, which is implemented in a cleaning chamber, where the cleaning solution sprayed along the door cleaning path is provided by a plurality of door nozzles configured inside the cleaning chamber.

4. The wet cleaning method for the door of FOUP defined in claim 3, wherein the cleaning chamber provides a support frame for placing the door, and the clamps are configured around a horizontal surface area of the support frame.

5. The wet cleaning method for the door of FOUP defined in claim 1, wherein, when the door is placed, the clamp swings under the gravity of the door to clamp the door, and, when the gravity of the door is removed, the clamp releases the door in an automatically swinging and resetting manner by virtue of the moment generated by its own gravity.

6. The wet cleaning method for the door of FOUP defined in claim 1, wherein the end wall also has at least one through-holes communicating with the inner compartment, and the clamp also covers the through-holes to avoid contact with the cleaning solution.

7. The wet cleaning method for the door of FOUP defined in claim 1, which further includes:
horizontally placing the shell such that the opening of the shell used for securing the door is exposed downward and the shell is positioned below the door; and
defining a shell inner wall cleaning path from inside to outside and a shell outer wall cleaning path from outside to inside; supplying cleaning solution to flush an inner wall of the shell along the shell inner wall cleaning path, and supplying cleaning solution to flush an outer wall of the shell along the shell outer wall cleaning path. Specifically, the outer wall of the shell is relatively adjacent to the outer surface of the door and relatively distant from the inner surface of the door.

8. The wet cleaning method for the door of FOUP defined in claim 7, wherein the door is placed after placement of the shell.

9. The wet cleaning method for the door of FOUP defined in claim 7, which is implemented in a cleaning chamber, wherein a plurality of nozzles configured around the cleaning chamber supply cleaning solution to flush along the door cleaning path, the shell inner wall cleaning path, and the shell outer wall cleaning path.

10. The wet cleaning method for the door of FOUP defined in claim 9, wherein the cleaning chamber provides a support frame for placing the door and the shell in different layers, and the clamps are configured around of a horizontal surface area of the support frame.

11. A wet cleaning method for the door of a FOUP, wherein the FOUP comprises the door and a shell to be locked by the door, the door has an outer surface exposed outside the shell, an inner surface located at the opposite side of the outer surface to be hidden inside the shell, the outer surface is formed with a plurality of functional slot holes, the inner surface is provided with an annular airtight seal ring for airtight connection with the shell, and the door is unlocked and separated from the shell before execution of the wet cleaning method, which includes:
horizontally placing the door so that the inner surface with the annular airtight seal ring is exposed upward and the outer surface with the functional slot holes is exposed downward; and
defining a door cleaning path from top to bottom and supplying cleaning solution to flush the inner surface and the airtight seal ring of the door along the door cleaning path; specifically, the door cleaning path excludes passing through the outer surface and the functional slot holes.

12. The wet cleaning method for the door of FOUP defined in claim 11, wherein the defined direction of the door cleaning path from top to bottom includes vertical, diagonal, or a combination thereof.

13. The wet cleaning method for the door of FOUP defined in claim 11, which is implemented in a cleaning chamber, where the cleaning solution sprayed along the door cleaning path is provided by a plurality of door nozzles configured inside the cleaning chamber.

14. The wet cleaning method for the door of FOUP defined in claim 13, wherein the cleaning chamber provides a support frame for placing the door.

15. The wet cleaning method for the door of FOUP defined in claim 11, which further includes:
horizontally placing the shell such that the opening of the shell used for securing the door is exposed downward and the shell is positioned below the door; and
defining a shell inner wall cleaning path from inside to outside and a shell outer wall cleaning path from outside to inside; supplying cleaning solution to flush an inner wall of the shell along the shell inner wall cleaning path, and supplying cleaning solution to flush an outer wall of the shell along the shell outer wall cleaning path. Specifically, the outer wall of the shell is relatively adjacent to the outer surface of the door and relatively distant from the inner surface of the door.

16. The wet cleaning method for the door of FOUP defined in claim 15, wherein the door is placed after placement of the shell.

17. The wet cleaning method for the door of FOUP defined in claim 15, which is implemented in a cleaning chamber, wherein a plurality of nozzles configured around the cleaning chamber supply cleaning solution to flush along the door cleaning path, the shell inner wall cleaning path, and the shell outer wall cleaning path.

18. The wet cleaning method for the door of FOUP defined in claim 17, wherein the cleaning chamber provides a support frame for placing the door and the shell in different layers.
